(19) United States
(12) Patent Application Publication
(10) Pub. No.: US 2017/0005290 A1
(43) Pub. Date: Jan. 5, 2017

(54) OPTOELECTRONIC COMPONENT AND METHOD FOR PRODUCING AN OPTOELECTRONIC COMPONENT

(71) Applicant: OSRAM OLED GMBH, Regensburg (DE)

(72) Inventor: Thomas Wehlus, Lappersdorf (DE)

(21) Appl. No.: 15/113,086

(22) PCT Filed: Jan. 20, 2015
(86) PCT No.: PCT/EP2015/051022

§ 371 Date: Jul. 21, 2016

(30) Foreign Application Priority Data
Jan. 21, 2014 (DE) 10 2014 100 627.5

(51) Int. Cl. H01L 51/52; H01L 51/56; H01L 51/44

(52) U.S. Cl. CPC H01L 51/5253; H01L 51/5206; H01L 51/5221; H01L 51/441; H01L 51/448; H01L 51/56; H01L 2251/5369

(57) ABSTRACT

An optoelectronic component may include a first electrically conductively formed layer, including an electrically conductive substance in a matrix, a second electrically conductively formed layer, and an electrically conductively formed thin film encapsulation between the first electrically conductively formed layer and the second electrically conductively formed layer. The electrically conductively formed thin film encapsulation is formed in such a way that the second electrically conductively formed layer is electrically conductively connected to the first electrically conductively formed layer by the electrically conductively formed thin film encapsulation, and the electrically conductively formed thin film encapsulation is formed in a hermetically impermeable fashion with respect to a diffusion of water and/or oxygen from the first electrically conductively formed layer through the electrically conductively formed thin film encapsulation into the second electrically conductively formed layer.

In various embodiments, an optoelectronic component and a method for producing an optoelectronic component are provided.

Light emitting large-area organic light emitting diodes (OLEDs) are efficient radiation sources and are being increasingly widely used in general lighting, for example as a surface light source.

An OLED may include an anode and a cathode with an organic functional layer system therebetween. The organic functional layer system may include one or a plurality of emitter layer(s) in which electromagnetic radiation is generated, one or a plurality of charge generating layer structure(s) each composed of two or more charge generating layers (CGLs) for charge generation, and one or a plurality of electron blocking layer(s), also designated as hole transport layer(s) (HTL), and one or a plurality of hole blocking layers, also designated as electron transport layer(s) (ETL), in order to direct the current flow.

By way of example, silver nanowires (Ag nanowires) or carbon nanotubes (C nanotubes) are used as material for the anode and/or cathode. Forming the anode and/or cathode therefrom involves embedding the nanowires or nanotubes in a binder. This mixture can be applied to a substrate. The binder can be hardened and, in the hardened state, physically and/or electrically connect the nanowires or nanotubes to one another and fix them on the substrate. Conventional binders have the disadvantage that they “become saturated” relatively rapidly with water and then transport the latter directly into the OLED. Conventionally, the nanowires, in order to reduce the contact with water, are therefore not led as far as the edge of the OLED, but rather are contacted by a metal structure led from the edge inward, to the nanowires.

For protection against harmful environmental influences, conventional OLEDs are surrounded with an encapsulation that is hermetically impermeable with respect to water and/or oxygen, for example a thin film encapsulation, a barrier thin-film layer, a barrier layer, an encapsulation layer, or a barrier film. Conductive thin film encapsulations are furthermore known.

In various embodiments, an optoelectronic component and a method for producing an optoelectronic component are provided which make it possible to form stabler optoelectronic components including a binder-containing electrode.

In various embodiments, an optoelectronic component is provided, the optoelectronic component including: a first electrically conductively formed layer, including an electrically conductive substance in a matrix; a second electrically conductively formed layer; and an electrically conductively formed thin film encapsulation between the first electrically conductively formed layer and the second electrically conductively formed layer; wherein the electrically conductively formed thin film encapsulation is formed in such a way that the second electrically conductively formed layer is electrically conductively connected to the first electrically conductively formed layer by the electrically conductively formed thin film encapsulation, and wherein the electrically conductively formed thin film encapsulation is formed in a hermetically impermeable fashion with respect to a diffusion of water and/or oxygen from the first electrically conductively formed layer through the electrically conductively formed thin film encapsulation into the second electrically conductively formed layer.

In various configurations, a layer or structure of an optoelectronic component is electrically conductively formed if it can conduct an electric current during the operation of the optoelectronic component or under operating conditions.

The electrically conductively formed layer or structure may include or be formed from, for example, an electrically conductive substance, for example a metal or a metal alloy, for example Al, Cu, MgAg, or one of the further examples described below. Alternatively or additionally, the electrically conductively formed layer or structure may include or be formed from a dielectric substance and/or a semiconducting substance.

In the case of an electrically conductively formed layer or structure composed of a dielectric substance or substance mixture, the electrically conductively formed layer or structure can be formed for example with a thickness in the current direction and/or a dielectric length of the current path such that an electric current can be transported through or via the dielectric layer or structure, for example by a tunneling current and/or electrically conductive channels in the dielectric layer or structure.

In the case of an electrically conductively formed layer or structure composed of a semiconducting substance or substance mixture, the electrically conductively formed layer or structure can be adapted with respect to the layer(s) or structure(s) directly electrically connected to the electrically conductively formed layer or structure, for example can be formed in a manner adapted with respect to the band structure and/or crystal direction in the current direction.

With respect to the band structure and/or crystal direction in the current direction of the semiconducting electrically conductively formed layer or structure, for example the energy level of the conduction band, of the valence band, of the Fermi level or of the effective Fermi level, of the chemical potential, of the lowest unoccupied molecule orbital (LUMO), of the highest occupied molecule orbital (HOMO), of the ionization energy and/or of the electron affinity can be taken into account when forming the semiconducting electrically conductively formed layer or structure with respect to the layer(s) or structure(s) directly electrically connected to the electrically conductively formed layer or structure, such that a current flow during the operation of the optoelectronic component can take place through the semiconducting electrically conductively formed layer or structure during operation.

In one configuration, the optoelectronic component can be formed as a surface component.

In one configuration, the optoelectronic component can be formed as an organic optoelectronic component, for example as an organic photodetector, an organic solar cell and/or an organic light emitting diode.

In one configuration, the first electrically conductively formed layer, the electrically conductively formed thin film encapsulation and the second electrically conductively formed layer are formed as a layer stack. The first electrically conductively formed layer, the electrically conductively formed thin film encapsulation and the second electrically conductively formed layer can have a substantially identical areal dimensioning, for example an identical areal dimensioning in the optically active region of the optoelectronic component.

In one configuration, the electrically conductively formed thin film encapsulation can have a first interface with the first electrically conductively formed layer and a second interface with the second electrically conductively formed layer, wherein the electrical connection of the first electrically conductively formed layer to the second electrically conductively formed layer is formed by the first interface and the second interface.

In one configuration, the first electrically conductively formed layer can have a thickness in a range of approximately 10 nm to approximately 2 μm.

In one configuration, in the first electrically conductively formed layer the electrically conductive substance can be distributed in the matrix.

In one configuration, the electrically conductive substance can be distributed homogeneously in the matrix.

In one configuration, the electrically conductive substance can be distributed in the matrix in such a way that the first electrically conductively formed layer has a gradient of electrically conductive substance, for example increasing or decreasing from an interface of the first electrically conductively formed layer to the center or another interface.

In one configuration, the electrically conductive substance can be formed in at least a first ply and a second ply, wherein the matrix is arranged between the first ply and the second ply and the matrix connects the first ply to the second ply.

In one configuration, the electrically conductive substance can form a two-dimensional network on the area.

In one configuration, the matrix may include or be formed from a binder with respect to the electrically conductive substance.

In one configuration, the matrix can be formed in a cohesion-reinforcing fashion with regard to the cohesion of the electrically conductive substance.

In one configuration, the matrix of the first electrically conductively formed layer can be hygroscopic.

In one configuration, the electrically conductive substance can be formed in particles in one of the following forms:

nanowires, nanotubes, flakes or laminae.

In one configuration, the particles of the electrically conductive substance can have an average diameter in a range of approximately 5 nm to approximately 1 μm, for example from approximately 10 nm to approximately 150 nm, for example from approximately 15 nm to approximately 60 nm, and/or a length in a range from the diameter of the corresponding nanowire to approximately 1 mm, for example from approximately 1 μm to approximately 100 μm, for example from approximately 20 μm to approximately 50 μm. The thickness of the layer formed by the nanowires during the production of the optoelectronic component can be for example approximately 100 nm to approximately 1 mm, for example approximately 1 μm to approximately 100 μm, for example approximately 20 μm to approximately 50 μm. The thickness of the layer formed by the nanowires in the completed optoelectronic component can thus be for example approximately 10 nm to approximately 2 μm, for example approximately 20 nm to approximately 300 nm, for example approximately 30 nm to approximately 180 nm.

In one configuration, the electrically conductive substance can be formed in the form of a graphene area.

In one configuration, the electrically conductive substance may include or be formed from one of the following substances: carbon, silver, copper, gold, aluminum, zinc, tin.

The electrically conductive substance, for example in the form of nanowires, may include or be formed from, for example, a metallic material, for example a metal or a semimetal, for example silver, gold, aluminum and/or zinc. For example, the nanowires may include an alloy including one or more of the materials mentioned.

The nanotubes may include or be formed from, for example, carbon, for example as single wall nanotubes (single wall carbon nanotube—SWCNT), multiwall nanotubes (multi wall carbon nanotube MWCNT), and/or functionalized nanotubes, for example including chemically functional groups on the outer skin of the nanotubes.

In one configuration, the nanowires can be at least partly atomically connected to one another. By way of example, the nanowires can form a two-dimensional network on account of their atomic connections.

In one configuration, the electrically conductively formed thin film encapsulation may include or be formed from one of the following substances: a metal oxide, a metal nitride, and/or a metal oxynitride, for example a substance of a barrier layer of the optoelectronic component, for example can be formed as a barrier layer of the optoelectronic component.

In one configuration, the electrically conductively formed thin film encapsulation can have a layer thickness in a range of approximately 0.1 nm to approximately 100 nm, for example in a range of approximately 30 nm to approximately 50 nm.

In one configuration, the electrically conductively formed thin film encapsulation may include or be formed from a dopant in a matrix.

In one configuration, the matrix of the electrically conductively formed thin film encapsulation may include or be formed from a transparent conductive oxide, for example zinc oxide, tin oxide, nickel oxide, and/or a copper delafossite.

In one configuration, the dopant of the electrically conductively formed thin film encapsulation may include or be a metal, for example silver, copper, gold, aluminum, zinc, tin.

In one configuration, the electrically conductively formed thin film encapsulation may include or be formed from zinc oxide doped with aluminum.

In one configuration, the electrically conductively formed thin film encapsulation may include or be formed from an alloy.

In one configuration, the electrically conductively formed thin film encapsulation may include or be formed from a transparent conductive oxide.

In one configuration, the electrically conductively formed thin film encapsulation may include or be formed from an electrically conductive substance, for example a metal or a semiconductor.

In one configuration, the electrically conductively formed thin film encapsulation may include or be formed from a dielectric material, for example in such a way that the electrical connection by the electrically conductively formed thin film encapsulation is formed by a tunneling current.

In one configuration, the electrically conductively formed thin film encapsulation can be formed in a planar fashion and have a thickness, wherein the electrical conductivity of the electrically conductively formed thin film encapsulation can be greater along the thickness than along the area.

In one configuration, the diffusion rate with respect to water and/or oxygen through the electrically conductively formed thin film encapsulation can be less than approximately 10⁻⁴ g/(m²d), for example in a of approximately 10⁻⁴ g/(m²d) to approximately 10⁻¹⁰ g/(m²d).

In one configuration, the first electrically conductively formed layer can have a higher resistance with respect to water and/or oxygen than the second electrically conductively formed layer, for example a lower solubility product and/or a low chemical reactivity.

In one configuration, the optoelectronic component may include a first electrode, a second electrode and an organic functional layer structure between the first electrode and the second electrode, wherein the organic functional layer structure is formed for converting an electric current into an electromagnetic radiation and/or for converting an electromagnetic radiation into an electric current; wherein the first electrically conductively formed layer is formed as first electrode and/or second electrode, for example in each case; and wherein the second electrically conductively formed layer is formed as the organic functional layer structure, or a layer or structure in the organic functional layer structure.

In one configuration, the optoelectronic component may furthermore include at least one further electrode in such a way that the first electrode and/or the second electrode are/is formed as intermediate electrode(s).

In one configuration, the electrically conductively formed thin film encapsulation can be electrically conductively connected to the first electrode and the second electrode and be structured in such a way that that region of the electrically conductively formed thin film encapsulation which is electrically conductively connected to the first electrode is electrically insulated from that region of the electrically conductively formed thin film encapsulation which is electrically conductively connected to the second electrode.

In one configuration, the optoelectronic component may furthermore include an encapsulation structure, wherein the encapsulation structure includes the electrically conductively formed thin film encapsulation, and wherein the encapsulation structure is formed in such a way that the second electrically conductively formed layer is hermetically sealed with respect to a diffusion of water and/or oxygen through the encapsulation structure into the second electrically conductively formed layer

In one configuration, the optoelectronic component may furthermore include at least one charge carrier injection layer between the electrically conductively formed thin film encapsulation and the first electrically conductively formed layer and/or between the electrically conductively formed thin film encapsulation and the second electrically conductively formed layer.

In various embodiments, a method for producing an optoelectronic component is provided, the method including: forming a first electrically conductive layer including an electrically conductive substance in a matrix in such a way that the first electrically conductive layer conducts at least part of the electric operating current during the operation of the optoelectronic component; forming a second electrically conductive layer in such a way that the second electrically conductive layer conducts at least part of the electric operating current during the operation of the optoelectronic component; and forming an electrically conductive thin film encapsulation between the first electrically conductive layer and the second electrically conductive layer, wherein the electrically conductive thin film encapsulation is formed in such a way that the second electrically conductive layer is electrically conductively connected to the first electrically conductive layer by the electrically conductive thin film encapsulation at least during the operation of the optoelectronic component, and wherein the electrically conductive thin film encapsulation is formed in a hermetically impermeable fashion with respect to a diffusion of water and/or oxygen from the first electrically conductive layer through the electrically conductive thin film encapsulation into the second electrically conductive layer.

In various configurations, an electrically conductive layer or structure which is formed in such a way that it conducts at least part of the electric operating current during the operation of the optoelectronic component is designated as an electrically conductively formed layer or structure.

In various configurations, the method for producing an optoelectronic component can have features of the optoelectronic component; and the optoelectronic component can have features of the method for producing an optoelectronic component, insofar as they are expediently applicable in each case.

In one configuration of the method, the electrically conductively formed thin film encapsulation can be formed over the whole area on or above the first electrically conductively formed layer or the second electrically conductively formed layer.

In one configuration of the method, the electrically conductively formed thin film encapsulation can be structured after being formed, for example by a laser.

In one configuration of the method, the method can furthermore include forming a first electrode and forming a second electrode, wherein the first electrode and/or the second electrode are/is formed in a manner electrically conductively connected to the electrically conductively formed thin film encapsulation.

In one configuration of the method, the electrically conductively formed thin film encapsulation can be structured in such a way that that region of the electrically conductively formed thin film encapsulation which is electrically conductively connected to the first electrode is electrically insulated from that region of the electrically conductively formed thin film encapsulation which is electrically conductively connected to the second electrode.

Embodiments of the invention are illustrated in the figures and are explained in greater detail below.

### IN THE FIGURES

FIG. 1 shows a schematic illustration of an optoelectronic component in accordance with various embodiments;

FIG. 2 shows a schematic illustration of a method for producing an optoelectronic component in accordance with various embodiments;

FIG. 3 shows a schematic illustration of an optoelectronic component in accordance with various embodiments; and

FIGS. 4A, B show schematic illustrations of optoelectronic components in accordance with various embodiments.

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

In various embodiments, optoelectronic components are described, wherein an optoelectronic component includes an optically active region. The optically active region can emit electromagnetic radiation by a voltage applied to the optically active region. In various embodiments, the optoelectronic compoment can be formed in such a way that the electromagnetic radiation has a wavelength range including x-ray radiation, UV radiation (A-C), visible light and/or infrared radiation (A-C).

In various configurations, the optically active region, for example an electromagnetic radiation emitting structure, can be an electromagnetic radiation emitting semiconductor structure and/or be formed as an electromagnetic radiation emitting diode, as an organic electromagnetic radiation emitting diode, as an electromagnetic radiation emitting transistor or as an organic electromagnetic radiation emitting transistor. The electromagnetic radiation emitting component can be formed for example as a light emitting diode (LED), as an organic light emitting diode (OLED), as a light emitting transistor or as an organic light emitting transistor, for example an organic field effect transistor (OFET) and/or an organic electronic system. The organic field effect transistor can be a so-called “all-OFET”, in which all the layers are organic. In various configurations, the electromagnetic radiation emitting component can be part of an integrated circuit. Furthermore, a plurality of electromagnetic radiation emitting components can be provided, for example in a manner accommodated in a common housing. An optoelectronic component may include an organic functional layer system, which is synonymously also designated as organic functional layer structure. The organic functional layer structure may include or be formed from an organic substance or an organic substance mixture which is formed for example for emitting an electromagnetic radiation from an electric current provided.

An organic light emitting diode can be formed as a so-called top emitter and/or a so called bottom emitter. In the case of a bottom emitter, electromagnetic radiation is emitted from the electrically active region through the carrier. In the case of a top emitter, electromagnetic radiation is emitted from the top side of the electrically active region and not through the carrier.

A top emitter and/or bottom emitter can also be formed as optically transparent or optically translucent; by way of example, each of the layers or structures described below can be or be formed as transparent or translucent with respect to the absorbed or emitted electromagnetic radiation.

A planar optoelectronic component including two planar, optically active sides can be formed for example as transparent or translucent in the connection direction of the optically active sides, for example as a transparent or translucent organic light emitting diode. A planar optoelectronic component can also be designated as a plane optoelectronic component.

However, the optically active region can also be formed in such a way that it has a planar, optically active side and a planar, optically inactive side, for example an organic light emitting diode formed as a top emitter or a bottom emitter. In various embodiments, the optically inactive side can be transparent or translucent, or be provided with a mirror structure and/or an opaque substance or substance mixture, for example for heat distribution. The beam path of the optoelectronic component can be directed on one side, for example.

The first electrode, the second electrode and the organic functional layer structure of the optoelectronic component can be formed in each case with a large area. As a result, the optoelectronic component may include a continuous luminous area which is not structured into functional partial regions, for example a luminous area segmented into functional regions or around a luminous area formed by a multiplicity of pixels. As a result, large area emission or absorption of electromagnetic radiation from the optoelectronic component can be made possible. In this case, “large area” can mean that the optically active side has an area, for example a continuous area, for example of greater than or equal to a few square millimeters, for example greater than or equal to one square centimeter, for example greater than or equal to one square decimeter. By way of example, the optoelectronic component may include only a single continuous luminous area brought about by the large-area and continuous formation of the electrodes and of the organic functional layer structure.

In the context of this description, a layer or structure that is hermetically impermeable with respect to water and/or oxygen can be understood as a substantially hermetically impermeable layer. A hermetically impermeable layer or structure can have for example a diffusion rate with respect to water and/or oxygen of less than approximately 10⁻¹ g/(m²d), for example a diffusion rate with respect to water and/or oxygen of less than approximately 10⁻⁴ g/(m²d), for example in a range of approximately 10⁻⁴ g/(m²d) to approximately 10⁻¹⁰ g/(m²d), for example in a range of approximately 10⁻⁴ g/(m²d) to approximately 10⁻⁶ g/(m²d). In various configurations, a substance that is hermetically impermeable with respect to water and/or oxygen or a hermetically impermeable substance mixture may include or be formed from a ceramic, a metal, a metal oxide, metal nitride and/or metal oxynitride.

In various embodiments, the term “translucent” or “translucent layer” can be understood to mean that a layer is transmissive to light, for example to the light generated by the light emitting component, for example in one or more wavelength ranges, for example to light in a wavelength range of visible light (for example at least in a partial range of the wavelength range of 380 nm to 780 nm). By way of example, in various embodiments, the term “translucent layer” should be understood to mean that substantially the entire quantity of light coupled into a structure (for example a layer) is also coupled out from the structure (for example layer), wherein part of the light can be scattered in this case.

In various embodiments, the term “transparent” or “transparent layer” can be understood to mean that a layer is transmissive to light (for example at least in a partial range of the wavelength range of 380 nm to 780 nm), wherein light coupled into a structure (for example a layer) is also coupled out from the structure (for example layer) without scattering or light conversion.

The term “atomic layer deposition” encompasses known methods in which, for producing a layer, the starting products (precursors) necessary therefor are not fed simultaneously but rather alternatively one after another to a coating chamber, also designated as reactor, with the substrate to be coated therein. In this case, the starting materials can deposit alternately on the surface of the substrate to be coated or on the previously deposited starting material and form a chemical compound therewith. As a result, it is possible per cycle repetition, that is to say the feeding of the necessary starting products in successive substeps, to grow in each case a maximum of one monolayer of the layer to be applied. Good control of the layer thickness is possible by the number of cycles. The starting material fed in first deposits only on the surface to be coated and only the second starting material fed in afterward can enter into chemical reactions with the first starting material. The chemical reactions of the starting products are limited, i.e. self-limited, by the number of reactants on the surface. A similar self-limiting surface reaction can be employed for forming organic films, for example polymer films, for example polyamide. This process of forming organic films can be referred to as a molecular layer deposition (MLD) method since part of a molecule is applied on the surface per cycle. The MLD precursors may include homobifunctional reactants; in other words, the starting products may each include two identical functional groups.

A self-terminating MLD reaction of each ply can be formed with heterobifunctional reactants; that is to say that each starting product may include two different functional groups. One of the functional groups can react with the chemical group of the surface, and the other cannot react therewith. As a result, the heterobifunctional reactants can be formed only in a monofunctional fashion and can thus prevent a double reaction among one another which might lead for example to a termination of the polymer chain. A very conformal layer growth can be made possible by ALD and MLD, wherein even surfaces having a high aspect ratio can be covered uniformly.

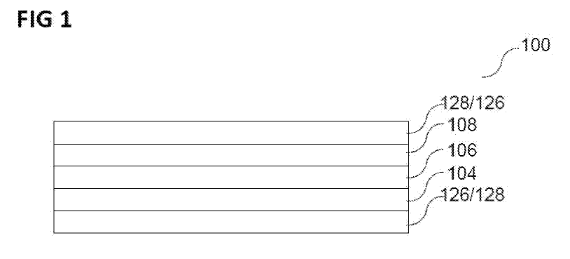

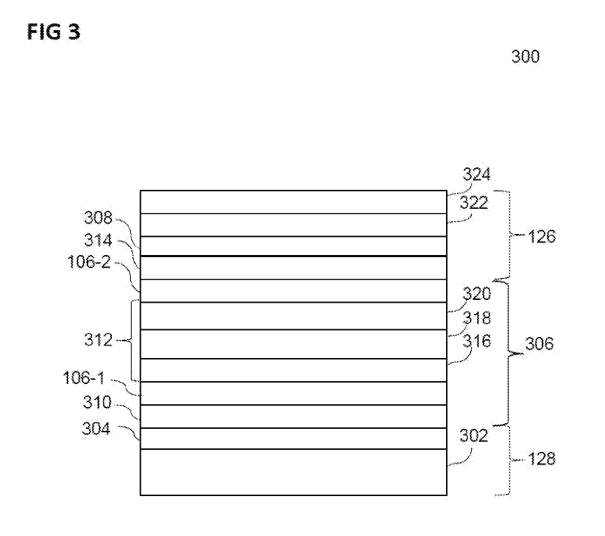

In various embodiments, the optoelectronic component 100 may include, on or above a hermetically impermeable substrate 128 or carrier 102 (see FIG. 3) and/or an encapsulation structure 126, a first electrically conductively formed layer 104, an electrically conductively formed thin film encapsulation 106 and a second electrically conductively formed layer 108—for example illustrated in FIG. 1.

Alternatively, the carrier 102, the hermetically impermeable substrate 128 and/or the encapsulation structure can be optional.

The optoelectronic component 100 can be formed for example as a surface component. An optoelectronic component 100 formed for example as an organic optoelectronic component 100 can be formed for example as an organic photodetector, an organic solar cell and/or an organic light emitting diode.

The first electrically conductively formed layer 104 includes an electrically conductive substance in a matrix. The first electrically conductively formed layer 104 can have a thickness in a range of approximately 10 nm to approximately 2 μm, for example of approximately 20 nm to approximately 300 nm, for example approximately 30 nm to approximately 180 nm.

The matrix may include or be formed from a binder with respect to the electrically conductive substance. In other words: the matrix can be formed in a cohesion-reinforcing fashion with regard to the cohesion of the electrically conductive substance. The matrix of the first electrically conductively formed layer 104 can be hygroscopic, that is to say water-binding.

The electrically conductive substance can be distributed, for example homogeneously, in the matrix. Alternatively, the electrically conductive substance can be distributed in the matrix in such a way that the first electrically conductively formed layer 104 has a gradient of electrically conductive substance. Alternatively, the electrically conductive substance can be formed in at least a first ply and a second ply, wherein the matrix is arranged between the first ply and the second ply and the matrix connects the first ply to the second ply.

In various embodiments, the electrically conductive substance can form a two-dimensional network. The electrically conductive substance can be formed in particles in one of the following forms: nanowires, nanotubes, flakes or laminae.

The particles of the electrically conductive substance can have an average diameter in a range of approximately 5 nm to approximately 1 μm, for example of approximately 10 nm to approximately 150 nm, for example of approximately 15 nm to approximately 60 nm, and/or a length in a range from the diameter of the corresponding nanowire to approximately 1 mm, for example of approximately 1 μm to approximately 100 μm, for example of approximately 20 μm to approximately 50 μm.

In one embodiment, the electrically conductive substance can be formed in the form of a graphene area. Alternatively or additionally, the electrically conductive substance may include or be formed from one of the following substances: carbon, silver, copper, gold, aluminum, zinc, tin.

The electrically conductive substance, for example in the form of nanowires, may include or be formed from, for example, a metallic material, for example a metal or a semimetal, for example silver, gold, aluminum and/or zinc. By way of example, the nanowires may include an alloy including one or a plurality of the materials mentioned. In one configuration, the nanowires can be at least partly atomically connected to one another. By way of example, the nanowires can form a two-dimensional network on account of their atomic connections.

The electrically conductive substance in the form of nanotubes may include or be formed from, for example, carbon, for example as single wall nanotubes (single wall carbon nanotube—SWCNT), multiwall nanotubes (multi wall carbon nanotube MWCNT), and/or functionalized nanotubes, for example including chemically functional groups on the outer skin of the nanotubes.

The electrically conductively formed thin film encapsulation 106 is arranged between the first electrically conductively formed layer 104 and the second electrically conductively formed layer 108. The electrically conductively formed thin film encapsulation 106 is formed in such a way that the second electrically conductively formed layer 108 is electrically conductively connected to the first electrically conductively formed layer 104 by the electrically conductively formed thin film encapsulation 106. Furthermore, the electrically conductively formed thin film encapsulation 106 is formed in such a way that the electrically conductively formed thin film encapsulation 106 is formed in a hermetically impermeable fashion with respect to a diffusion of water and/or oxygen from the first electrically conductively formed layer 104 through the electrically conductively formed thin film encapsulation 106 into the second electrically conductively formed layer 108.

The first electrically conductively formed layer 104, the electrically conductively formed thin film encapsulation 106 and the second electrically conductively formed layer 108 can be formed for example as a layer stack. The first electrically conductively formed layer 104, the electrically conductively formed thin film encapsulation 106 and the second electrically conductively formed layer 108 can have a substantially identical areal dimensioning, for example an identical areal dimensioning in the optically active region of the optoelectronic component 100.

In one embodiment, the electrically conductively formed thin film encapsulation 106 can have a first interface with the first electrically conductively formed layer 104 and a second interface with the second electrically conductively formed layer 108. The electrical connection of the first electrically conductively formed layer 104 to the second electrically conductively formed layer 108 can be formed by the first interface and the second interface and/or by the first interface and the second interface.

In various embodiments, the electrically conductively formed thin film encapsulation 106 may include or be formed from one of the following substances: a metal oxide, a metal nitride, and/or a metal oxynitride, for example a substance of the barrier layer of the optoelectronic component—as is shown in the description below.

The electrically conductively formed thin film encapsulation 106 can have a layer thickness in a range of approximately 0.1 nm to approximately 100 nm, for example in a range of approximately 10 nm to approximately 100 nm, for example in a range of approximately 20 nm to approximately 50 nm, for example in a range of approximately 30 nm to approximately 50 nm.

In various embodiments, the electrically conductively formed thin film encapsulation 106 may include or be formed from a dopant in a matrix. The matrix may include or be formed from a conductive oxide, for example zinc oxide, tin oxide, nickel oxide, and/or a copper delafossite; and can additionally be for example transparent to visible light. The dopant may include or be a metal, for example silver, copper, gold, aluminum, zinc, tin. By way of example, the electrically conductively formed thin film encapsulation 106 may include or be formed from zinc oxide doped with aluminum. Alternatively, additionally or in other words, the electrically conductively formed thin film encapsulation 106 may include or be formed from an alloy.

In various embodiments, the electrically conductively formed thin film encapsulation can have an atomic proportion of dopant in the atomic sites of the matrix of the electrically conductively formed thin film encapsulation 106 in a range of approximately 0.1% to approximately 20%, for example in a range of approximately 0.5% to approximately 10%, for example in a range of approximately 1% to approximately 4%. For example 3% of aluminum in zinc oxide.

In various embodiments, the electrically conductively formed thin film encapsulation can have a proportion by weight of dopant in the electrically conductively formed thin film encapsulation 106 in a range of approximately 0.1% to approximately 20%, for example in a range of approximately 0.5% to approximately 10%, for example in a range of approximately 1% to approximately 4%. For example 3% of aluminum in zinc oxide.

In other words: in various embodiments, the electrically conductively formed thin film encapsulation 106 may include or be formed from a metal, a semiconducting material and/or a dielectric material. In the case of an electrically conductively formed thin film encapsulation 106 including a dielectric material, the electrically conductively formed thin film encapsulation 106 can be formed in such a way that the electrical connection by the electrically conductively formed thin film encapsulation 106 is formed by a tunneling current.

The electrically conductively formed thin film encapsulation 106 can be formed in a planar fashion and have a thickness, wherein the electrical conductivity of the electrically conductively formed thin film encapsulation 106 can be greater along the thickness than along the area.

The electrically conductively formed thin film encapsulation 106 should be formed in a hermetically impermeable fashion with respect to water and/or oxygen, for example have a diffusion rate with respect to water and/or oxygen through the electrically conductively formed thin film encapsulation 106 which is less than approximately 10⁻⁴ g/(m²d), for example in a of approximately 10⁻⁴ g/(m²d) to approximately 10⁻¹⁰ g/m²d).

The second electrically conductively formed layer 108 can generally be a layer or a structure that is formed from a substance or substance mixture that has a higher chemical reactivity with respect to a substance than the first electrically conductively formed layer 104 and is impermeable, that is to say is hermetically impermeable, to the electrically conductively formed thin film encapsulation 106. In other words: the first electrically conductively formed layer 104 can have a higher resistance with respect to water and/or oxygen than the second electrically conductively formed layer 108, for example a lower solubility product and/or a low chemical reactivity. Therefore, the second electrically conductively formed layer 106 should be protected against water and/or oxygen for example from the direction of the first electrically conductively formed layer 104, for example by the electrically conductively formed thin film encapsulation.

In one configuration, the optoelectronic component 100 can furthermore include at least one charge carrier injection layer between the electrically conductively formed thin film encapsulation 106 and the first electrically conductively formed layer 104 and/or between the electrically conductively formed thin film encapsulation 106 and the second electrically conductively formed layer 108, as is also shown in the description below.

Further embodiments are illustrated for example in the description of FIG. 3.

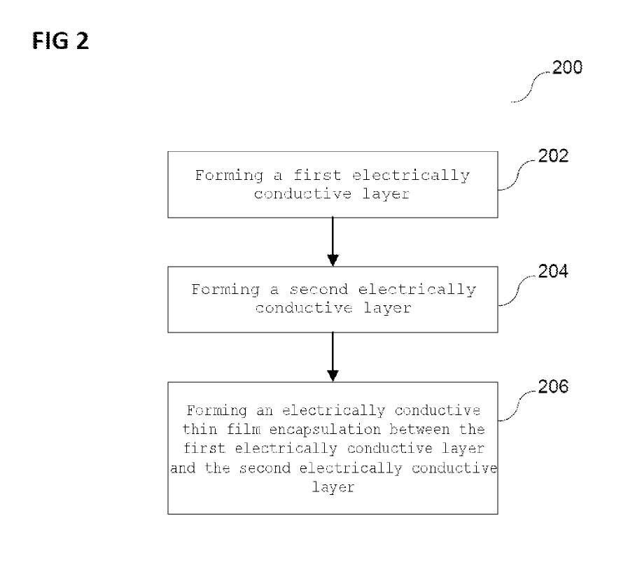

In various embodiments, a method 200 for producing an optoelectronic component 100 is provided—illustrated in FIG. 2.

In various embodiments, the optoelectronic component 100 can be formed as a surface component. An optoelectronic component 100 formed for example as an organic optoelectronic component 100 can be formed for example as an organic photodetector, an organic solar cell and/or an organic light emitting diode.

The method may include forming 202 a first electrically conductively formed layer 104 including an electrically conductive substance in a matrix.

The first electrically conductively formed layer 104 during the production of the optoelectronic component 100 can have a thickness in a range of approximately 100 nm to approximately 1 mm, for example in a range of approximately 1 μm to approximately 100 μm, for example in a range of approximately 20 μm to approximately 50 μm. The thickness of the first electrically conductively formed layer 104 can change, for example decrease, in the course of the method 200 for producing the optoelectronic component 100, for example by virtue of volatile constituents, for example organic solvents, being removed from the matrix, for example a binder. The first electrically conductively formed layer 104 in the completed optoelectronic component 100 can have for example a thickness in a range of approximately 10 nm to approximately 2 μm, for example approximately 20 nm to approximately 300 nm, for example approximately 30 nm to approximately 180 nm. In other words: in various embodiments, the first electrically conductively formed layer 104 including a binder-containing substance mixture including electrically conductive substance can be applied, for example in the form of a paste, for example by a screen printing method or a pad printing method, or be deposited, for example be sprayed, on or above a substrate. Afterward, the paste can be dried for example by heating and/or a vacuum. During drying, volatile constituents, for example an organic solvent, can be removed from the paste. Furthermore, the paste can be cured, for example by crosslinking of the electrically conductive substance.

The matrix may include or be formed from a binder with respect to the electrically conductive substance. By way of example, the electrically conductive substance can be distributed, for example intermixed, in the binder before the first electrically conductively formed layer 104 is formed. The binder can be a conventional binder for the respective electrically conductive substance, for example on a polymer basis, and include volatile substance, for example organic solvents. In other words: the matrix can be formed in a cohesion-reinforcing fashion with regard to the cohesion of the electrically conductive substance. The matrix of the first electrically conductively formed layer 104 can be hygroscopic, that is to say water-binding.

In various embodiments, the matrix of the paste for forming 202 the first electrically conductively formed layer 104 and/or the matrix of the first electrically conductively formed layer 104 may include, besides the electrically conductive substance, a solvent, for example an organic solvent, and further additives. The further additives can be for example: a hardener, a catalyst, a wetting agent, a foam inhibitor, a corrosion inhibitor, an antiwear additive and/or a stabilizer.

A solvent can be or include for example one of the following substances: water, a lower alcohol, for example ethanol, 2-propanol, n-propanol, methanol; and a polyhydric alcohol, for example ethylene glycol, glycerol, polymers including a hydroxyl group, for example polyethylene oxide; silicone oils, ethers of polyhydric alcohols, for example triethylene glycol-mono-n-butyl ether.

A binder can be or include for example one of the following substances: a cellulose-based system, for example a cellulose ether, for example methyl cellulose, ethyl cellulose, carboxymethyl cellulose; a cellulose ester, for example cellulose acetate, cellulose propionate, cellulose acetate butyrate; or other cellulose derivatives, for example nitrocellulose; an acrylate, a polyamide, a polyvinyl chloride, a polyethylene, a polyester, a polyurethane and/or an epoxy resin. Alternatively or additionally the matrix may include an inorganic binder, for example on an oxidic basis or on the basis of silicate, for example a silicic acid, a pyrogenic silicic acid; or on the basis of water glass, for example a slightly alkaline glass.

Furthermore, the matrix and/or the surface of the particles including electrically conductive substance may include chemisorbent compounds containing conjugated pi electron systems, for example electrically conductive polymers, for example poly(3,4-ethylene dioxythiophene) poly(styrene sulfonate) (PEDOT:PSS) and polyaniline (Pani), and the monomers or oligomers thereof.

A corrosion inhibitor may include or be for example mercaptobenzooxazole, mercaptobenzthiazoles.

In various embodiments, the first electrically conductively formed layer can have a proportion by weight of electrically conductive substance in the first electrically conductively formed layer in a range of approximately 0.1% by weight to approximately 100% by weight, for example in a range of approximately 1% by weight to approximately 80% by weight, for example in a range of approximately 5% by weight to approximately 70% by weight, for example in a range of approximately 15% by weight to approximately 50% by weight, for example in a range of approximately 20% by weight to approximately 40% by weight.

In various embodiments, the first electrically conductively formed layer 104 can be formed in such a way that the electrically conductive substance is distributed, for example homogeneously, in the matrix. Alternatively, the electrically conductive substance can be distributed in the matrix in such a way that the first electrically conductively formed layer 104 has a gradient of electrically conductive substance. Alternatively, the electrically conductive substance can be formed in at least a first ply and a second ply, wherein the matrix is arranged between the first ply and the second ply and the matrix connects the first ply to the second ply.

In various embodiments, the electrically conductive substance can be formed as a two-dimensional network. The electrically conductive substance can be formed in particles in one of the following forms: nanowires, nanotubes, flakes or laminae.

The particles of the electrically conductive substance can have an average diameter in a range of approximately 5 nm to approximately 1 μm, for example of approximately 10 nm to approximately 150 nm, for example of approximately 15 nm to approximately 60 nm, and/or a length in a range from the diameter of the corresponding nanowire to approximately 1 mm, for example of approximately 1 μm to approximately 100 μm, for example of approximately 20 μm to approximately 50 μm.

In one embodiment, the electrically conductive substance can be formed in the form of a graphene area. Alternatively or additionally, the electrically conductive substance may include or be formed from one of the following substances: carbon, silver, copper, gold, aluminum, zinc, tin.

The electrically conductive substance, for example in the form of nanowires, may include or be formed from, for example, a metallic material, for example a metal or a semimetal, for example silver, gold, aluminum and/or zinc. By way of example, the nanowires may include an alloy including one or a plurality of the materials mentioned. In one configuration, the nanowires can be at least partly atomically connected to one another. By way of example, the nanowires can form a two-dimensional network on account of their atomic connections.

The electrically conductive substance in the form of nanotubes may include or be formed from, for example, carbon, for example as single wall nanotubes (single wall carbon nanotube—SWCNT), multiwall nanotubes (multi wall carbon nanotube MWCNT), and/or functionalized nanotubes, for example including chemically functional groups on the outer skin of the nanotubes.

Furthermore, the method may include forming 204 a second electrically conductively formed layer 108.

In various embodiments, the method 200 may include forming a first electrode 310, forming a second electrode 314, and forming an organic functional layer structure 312 between the first electrode and the second electrode 310.

The organic functional layer structure 312 is formed for converting an electric current into an electromagnetic radiation and/or for converting an electromagnetic radiation into an electric current.

In various embodiments, the first electrically conductively formed layer 104 (illustrated by the reference signs 104-1 and 104-2 in FIG. 3) can be formed as first electrode 310 and/or second electrode 314. The second electrically conductively formed layer 108 can be formed as the organic functional layer structure 312, or a layer or structure in the organic functional layer structure 312. With regard to the configurations of the second electrically conductively formed layer 108, also see, for example, the description of the organic functional layer structure below.

The method 200 can furthermore include at least forming a further electrode in such a way that the first electrode 310 and/or the second electrode 314 are/is formed as intermediate electrode(s). Alternatively or additionally the first electrode 310 or the second electrode 314 and an intermediate electrode 318 can form the first electrode and the second electrode.

Furthermore, the method may include forming 206 an electrically conductively formed thin film encapsulation 106, wherein the electrically conductively formed thin film encapsulation 106 is formed between the first electrically conductively formed layer 104 and the second electrically conductively formed layer 108.

In one embodiment, the electrically conductively formed thin film encapsulation 106 can be formed on or above the first electrically conductively formed layer 104, and the second electrically conductively formed layer 108 can be formed on or above the electrically conductively formed thin film encapsulation 106. In another embodiment, the electrically conductively formed thin film encapsulation 106 can be formed on or above the second electrically conductively formed layer 108, and the first electrically conductively formed layer 104 can be formed on or above the electrically conductively formed thin film encapsulation 106. In other words: in various embodiments, the electrically conductively formed thin film encapsulation 106 is formed between the first electrically conductively formed layer 104 and the second electrically conductively formed layer 108.

The electrically conductively formed thin film encapsulation 106 can be formed in such a way that the second electrically conductively formed layer 108 is electrically conductively connected to the first electrically conductively formed layer 104 by the electrically conductively formed thin film encapsulation 106.

In one embodiment, the first electrically conductively formed layer 104, the electrically conductively formed thin film encapsulation 106 and the second electrically conductively formed layer 108 can be formed in such a way that the electrically conductively formed thin film encapsulation 106 has a first interface with the first electrically conductively formed layer 104 and a second interface with the second electrically conductively formed layer 108. The electrical connection of the first electrically conductively formed layer 104 to the second electrically conductively formed layer 108 can then be formed by the first interface and the second interface and/or by the first interface and the second interface.

Furthermore, the first electrically conductively formed layer 104 can have a higher resistance with respect to water and/or oxygen than the second electrically conductively formed layer 108, for example a lower solubility product and/or a low chemical reactivity. Therefore, the second electrically conductively formed layer 106 should be protected against water and/or oxygen for example from the direction of the first electrically conductively formed layer 104, for example by the electrically conductively formed thin film encapsulation 106. For this purpose, the electrically conductively formed thin film encapsulation 106 should be formed in a hermetically impermeable fashion with respect to water and/or oxygen, for example have a diffusion rate with respect to water and/or oxygen through the electrically conductively formed thin film encapsulation 106 which is less than approximately 10⁻⁴ g/(m²d), for example in a of approximately 10⁻⁴ g/(m²d) to approximately 10⁻¹⁰ g/(m²d). In various embodiments, the electrically conductively formed thin film encapsulation 106 can be formed in a hermetically impermeable fashion with respect to a diffusion of water and/or oxygen from the first electrically conductively formed layer 104 through the electrically conductively formed thin film encapsulation 106 into the second electrically conductively formed layer 108, for example by virtue of the electrically conductively formed thin film encapsulation 106 being formed from a hermetically impermeable substance.

In various embodiments, the electrically conductively formed thin film encapsulation 106 may include or be formed from one of the following substances: a ceramic, a metal oxide, a metal, a metal nitride, and/or a metal oxynitride, for example a substance of the barrier layer of the optoelectronic component 100—as is shown in the description below.

The electrically conductively formed thin film encapsulation 106 can have a layer thickness in a range of approximately 0.1 nm to approximately 100 nm, for example in a range of approximately 10 nm to approximately 100 nm, for example in a range of approximately 20 nm to approximately 50 nm, for example in a range of approximately 30 nm to approximately 50 nm.

In various embodiments, the electrically conductively formed thin film encapsulation 106 may include or be formed from a dopant in a matrix. The matrix may include or be formed from a conductive oxide, for example zinc oxide, tin oxide, nickel oxide, and/or a copper delafossite; and can additionally be for example transparent to visible light. The dopant may include or be a metal, for example silver, copper, gold, aluminum, zinc, tin. By way of example, the electrically conductively formed thin film encapsulation 106 may include or be formed from zinc oxide doped with aluminum. Alternatively, additionally or in other words, the electrically conductively formed thin film encapsulation 106 may include or be formed from an alloy.

In other words: in various embodiments, the electrically conductively formed thin film encapsulation 106 may include or be formed from a metal, a semiconducting material and/or a dielectric material.

In the case of an electrically conductively formed thin film encapsulation 106 including a dielectric material, the electrically conductively formed thin film encapsulation 106 can be formed in such a way that the electrical connection by the electrically conductively formed thin film encapsulation 106 is formed by a tunneling current.

The electrically conductively formed thin film encapsulation 106 can be formed in a planar fashion and have a thickness, wherein the electrical conductivity of the electrically conductively formed thin film encapsulation 106 can be greater along the thickness than along the area.

In one embodiment, the electrically conductively formed thin film encapsulation 104 can be formed by coevaporation, an atomic layer deposition (ALD) method and/or a molecular layer deposition (MLD) method. By way of example, an electrically conductively formed thin film encapsulation 104 can be formed with or from ZnO:Al by ALD.

| | Precursor | Resulting |
|---|---|---|
| Precursor | complement | compound |
| Trimethylaluminum | H₂O; Ethylene glycol; | Alucone |
| (Al(CH₃)₃ - TMA) | O₃; O₂ plasma, OH | (Al₂O₃) |
| | groups | |
| BBr₃ | H₂O | B₂O₃ |
| Tris(dimethylamino) | H₂O₂ | SiO₂ |
| silane | | |
| Cd(CH₃)₂ | H₂S | CdS |
| Hf[N(Me₂)]₄ | H₂O | HfO₂ |
| Pd(hfac)₂ | H₂; H₂ plasma | Pd |
| MeCpPtMe₃ | O₂ plasma | PtO₂ |
| MeCpPtMe₃ | O₂ plasma; O2 | Pt |
| | plasma + H2 | |
| Si(NCO)₄; SiCl₄ | H₂O | SiO₂ |
| TDMASn | H₂O₂ | SnO₂ |
| C₁₂H₂₆N₂Sn | H₂O₂ | SnOₓ |
| TaCl₅ | H₂O | Ta₂O₅ |
| Ta[N(CH₃)₂]₅ | O₂ plasma | Ta₂O₅ |
| TaCl₅ | H plasma | Ta |
| TiCl₄ | H plasma | Ta |
| Ti[OCH(CH₃)]₄; TiCl₄ | H₂O | TiO₂ |
| VO(OC₃H₉)₃ | O₂ | V₂O₅ |
| Zn(CH₂CH₃)₂ | H₂o; H₂O₂ | ZnO |
| Zr(N(CH₃)₂)₄)₂ | H₂O | ZrO₂ |
| Bis(ethylcyclopenta- | H₂O | MgO |
| dienyl)magnesium | | |
| Tris(diethylamido) | N₂H₄ | TaN |
| (tert-butylimido) | | |
| tantalum | | |

A selection of substances as MLD precursor, which selection should not be regarded as restrictive, is presented for example in the following overview.

| | Precursor | Resulting |
|---|---|---|
| Precursor | complement | compound |
| p-Phenylene diamines | Terephthaloyl chloride | Poly(p-phenylene |
| | | terephthalamide) |
| 1,6-Hexanediamine | C₆H₈Cl₂O₂ (adipoyl | Nylon 66 |
| | chloride) | |

In one embodiment of the method 200, the electrically conductively formed thin film encapsulation 106 can be formed over the whole area on or above the first electrically conductively formed layer 104 or the second electrically conductively formed layer 108. The electrically conductively formed thin film encapsulation 106 can be structured after being formed, for example by a laser. In one embodiment, in which the method furthermore includes forming a first electrode 310 and forming a second electrode 314, the first electrode and the second electrode can be formed in a manner electrically conductively connected to the electrically conductively formed thin film encapsulation. The electrically conductively formed thin film encapsulation 106 can be structured for example in such a way that that region of the electrically conductively formed thin film encapsulation 106 which is electrically conductively connected to the first electrode 310 is electrically insulated from that region of the electrically conductively formed thin film encapsulation 106 which is electrically conductively connected to the second electrode.

In various embodiments, the method 200 can furthermore include forming an encapsulation structure 126. The encapsulation structure 126 can be formed in such a way that the encapsulation structure 126 includes the electrically conductively formed thin film encapsulation 106. The encapsulation structure 126 can be formed in such a way that the second electrically conductively formed layer 108 is hermetically sealed with respect to a diffusion of water and/or oxygen through the encapsulation structure 126 into the second electrically conductively formed layer 108.

In various embodiments, the method 200 can furthermore include at least forming a charge carrier injection layer between the electrically conductively formed thin film encapsulation 106 and the first electrically conductively formed layer 104 and/or between the electrically conductively formed thin film encapsulation 106 and the second electrically conductively formed layer 108. The charge carrier injection layer can be for example a hole injection layer or an electron injection layer; also see for example descriptions of FIG. 3.

The first electrically conductively formed layer 104, the electrically conductively formed thin film encapsulation 106 and the second electrically conductively formed layer 108 can be formed for example as a layer stack. The first electrically conductively formed layer 104, the electrically conductively formed thin film encapsulation 106 and the second electrically conductively formed layer 108 can have a substantially identical areal dimensioning, for example an identical areal dimensioning in the optically active region, for example planar light emitting region, of the optoelectronic component 100.

In various embodiments, the optoelectronic component 100 includes the hermetically impermeable substrate 126, an active region 306 and the encapsulation structure 128—for example illustrated in FIG. 3.

The hermetically impermeable substrate 128 may include a carrier 302 and a first barrier layer 304.

The active region 306 is an electrically active region 306 and/or an optically active region 306. The active region 306 is for example that region of the optoelectronic component 100 in which electric current for the operation of the optoelectronic component 100 flows and/or in which electromagnetic radiation is generated and/or absorbed. In various embodiments, the optoelectronic component 100, for example the electrically active region 106, may include a first electrode 310, a second electrode 314 and an organic functional layer structure 312 between the first electrode 310 and the second electrode 314 (illustrated in FIG. 3), wherein the organic functional layer structure 312 is formed for converting an electric current into an electromagnetic radiation and/or for converting an electromagnetic radiation into an electric current; wherein the first electrically conductively formed layer 104 (illustrated by the reference signs 104-1 and 104-2 in FIG. 3) can be formed as first electrode 310 and/or second electrode 314; and wherein the second electrically conductively formed layer 108 is formed as the organic functional layer structure 312, or a layer or structure in the organic functional layer structure 312.

The optoelectronic component 100 can furthermore include at least one further electrode in such a way that the first electrode and/or the second electrode are/is formed as intermediate electrode(s). Alternatively or additionally, the first electrode or the second electrode and an intermediate electrode 318 can form the first electrode and the second electrode.

The organic functional layer structure 312 may include one, two or more functional layer structure units and one, two or more intermediate layer structure(s) between the layer structure units. The organic functional layer structure 312 may include for example a first organic functional layer structure unit 316, an intermediate layer structure 318 and a second organic functional layer structure unit 320.

The encapsulation structure 126 may include the electrically conductively formed thin film encapsulation 106. The encapsulation structure 126 is formed in such a way that the second electrically conductively formed layer 108 is hermetically sealed with respect to a diffusion of water and/or oxygen through the encapsulation structure 126 into the second electrically conductively formed layer 108. The encapsulation structure 128 can furthermore include the first barrier layer, a second barrier layer 308, a close connection layer 322 and a cover 324, wherein the electrically conductively formed thin film encapsulation can be formed as the first or second barrier layer 304, 308, and vice versa.

The first barrier layer 304 may include or be formed from one of the following materials: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, poly(p-phenylene terephthalamide), nylon 66, and mixtures and alloys thereof.

The first barrier layer 304 can be formed by one of the following methods: an atomic layer deposition (ALD) method, for example a plasma enhanced atomic layer deposition (PEALD) method or a plasmaless atomic layer deposition (PLALD) method; a chemical vapor deposition (CVD) method, for example a plasma enhanced chemical vapor deposition (PECVD) method or a plasmaless chemical vapor deposition (PLCVD) method; or alternatively by other suitable deposition methods.

In the case of a first barrier layer 304 including a plurality of partial layers, all the partial layers can be formed by an atomic layer deposition method. A layer sequence including only ALD layers can also be designated as a “nanolaminate”.

In the case of a first barrier layer 304 including a plurality of partial layers, one or a plurality of partial layers of the first barrier layer 304 can be deposited by a different deposition method than an atomic layer deposition method, for example by a vapor deposition method.

The first barrier layer 304 can have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

The first barrier layer 304 may include one or a plurality of high refractive index materials, for example one or a plurality of materials having a high refractive index, for example having a refractive index of at least 2.

Furthermore, it should be pointed out that, in various embodiments, a first barrier layer 304 can also be entirely dispensed with, for example for the case where the carrier 102 is formed in a hermetically impermeable fashion, for example includes or is formed from glass, metal, metal oxide.

The first electrode 304 can be formed as an anode or as a cathode.

The first electrode 310 may include or be formed from one of the following electrically conductive materials: a metal; a transparent conductive oxide (TCO); a network composed of metallic nanowires and nanoparticles, for example composed of Ag, which are combined with conductive polymers, for example; a network composed of carbon nanotubes which are combined with conductive polymers, for example; graphene particles and graphene layers; a network composed of semiconducting nanowires; an electrically conductive polymer; a transition metal oxide; and/or the composites thereof. The first electrode 310 composed of a metal or including a metal may include or be formed from one of the following materials: Ag, Pt, Au, Mg, Al, Ba, In, Ca, Sm or Li, and compounds, combinations or alloys of these materials. The first electrode 310 may include as transparent conductive oxide one of the following materials: for example metal oxides: for example zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AlZnO, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs and can be used in various embodiments. Furthermore, the TCOs do not necessarily correspond to a stoichiometric composition and can furthermore be p-doped or n-doped or be hole-conducting (p-TCO), or electron-conducting (n-TCO).

The first electrode 310 may include a layer or a layer stack of a plurality of layers of the same material or different materials. The first electrode 310 can be formed by a layer stack of a combination of a layer of a metal on a layer of a TCO, or vice versa. One example is a silver layer applied on an indium tin oxide layer (ITO) (Ag on ITO) or ITO-Ag-ITO multilayers.

The first electrode 304 can have for example a layer thickness in a range of 10 nm to 500 nm, for example of less than 25 nm to 250 nm, for example of 50 nm to 100 nm.

The first electrode 310 can have a first electrical terminal, to which a first electrical potential can be applied. The first electrical potential can be provided by an energy source, for example a current source or a voltage source. Alternatively, the first electrical potential can be applied to an electrically conductive carrier 102 and the first electrode 310 can be electrically supplied indirectly through the carrier 102. The first electrical potential can be for example the ground potential or some other predefined reference potential.

FIG. 3 illustrates an optoelectronic component 100 including a first organic functional layer structure unit 316 and a second organic functional layer structure unit 320. In various embodiments, however, the organic functional layer structure 312 can also include more than two organic functional layer structures, for example 3, 4, 5, 6, 7, 8, 9, 10, or even more, for example 15 or more, for example 70.

In various embodiments, one layer or a plurality of layers of the layers and structures described below can be or form the second electrically conductively formed layer.

The first organic functional layer structure unit 316 and the optionally further organic functional layer structures can be formed identically or differently, for example include an identical or different emitter material. The second organic functional layer structure unit 320 or the further organic functional layer structure units can be formed like one of the below-described configurations of the first organic functional layer structure unit 316.

The first organic functional layer structure unit 316 may include a hole injection layer, a hole transport layer, an emitter layer, an electron transport layer and an electron injection layer.

In an organic functional layer structure unit 312, one or a plurality of the layers mentioned can be provided, wherein identical layers can have a physical contact, can be only electrically connected to one another or can even be formed in a manner electrically insulated from one another, for example can be arranged alongside one another. Individual layers of the layers mentioned can be optional.

A hole injection layer can be formed on or above the first electrode 310. The hole injection layer may include or be formed from one or a plurality of the following materials: HAT-CN, Cu(I)pFBz, MoOₓ, WOₓ, VOₓ, ReOₓ, F4-TCNQ, NDP-2, NDP-9, Bi(III)pFBz, F16CuPc; NPB (N,N′-bis(naphthalen-1-yl)-N,N′-bis(phenyl)benzidine); beta-NPB N,N′-bis(naphthalen-2-yl)-N,N′-bis(phenyl)benzidine); TPD (N,N′-bis(3-methylphenyl)-N,N′-bis(phenyl)benzidine); spiro-TPD (N,N′-bis(3-methylphenyl)-N,N′-bis(phenyl)benzidine); spiro-NPB (N,N′-bis(naphthalen-1-yl)-N,N′-bis(phenyl)spiro); DMFL-TPD N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetrakis(n,n-diphenylamino)-9,9′-spirobifluorene); 9,9-bis[4-(N,N-bisbiphenyl-4-yl-amino)phenyl]-9H-fluorene; 9,9-bis[4-(N,N-bis-naphthalen-2-ylamino)phenyl]-9H-fluorene; 9, 9-bis[4-(N,N′-bisnaphthalen-2-yl-N,N′-bisphenylamino)phenyl]-9H-fluorene; N,N′-bis(phenanthren-9-yl)-N,N′-bis(phenyl)benzidine; 2,7-bis[N,N-bis(9,9-spirobifluoren-2-yl)amino)-9,9-spirobifluorene; 2,2′-bis[N,N-bis(biphenyl-4-yl)amino]9,9-spirobifluorene; 2,2′-bis(N,N-diphenylamino)9,9-spirobifluorene; di-[4-(N,N-ditolylamino)phenyl]cyclohexane; 2,2′,7,7′-tetra(N,N-ditolyl)aminospirobifluorene; and/or N,N,N′,N′-tetra-naphthalen-2-ylbenzidine.

The hole injection layer can have a layer thickness in a range of approximately 10 nm to approximately 1000 nm, for example in a range of approximately 30 nm to approximately 300 nm, for example in a range of approximately 50 nm to approximately 200 nm.

A hole transport layer can be formed on or above the hole injection layer. The hole transport layer may include or be formed from one or a plurality of the following materials: NPB (N,N′-bis(naphthalen-l-yl)-N,N′-bis(phenyl)benzidine); beta-NPB N,N′-bis(naphthalen-2-yl)-N,N′-bis(phenyl)benzidine); TPD (N,N′-bis(3-methylphenyl)-N,N′-bis(phenyl)benzidine); spiro TPD (N,N′-bis(3-methylphenyl)-N,N′-bis(phenyl)benzidine); spiro-NPB (N,N′-bis(naphthalen-1-y1)-N,N′-bis(phenyl)spiro); DMFL-TPD N,N′-bis(3-methylphenyl)-N,N′-bis(phenyl)-9,9-dimethylfluorene); DMFL-NPB (N,N′-bis(naphthalen-1-yl)-N,N′-bis(phenyl)-9,9-dimethylfluorene); DPFL-TPD (N,N′-bis(3-methylphenyl)-N,N′-bis(phenyl)-9,9-diphenylfluorene); DPFL-NPB (N,N′-bis(naphthalen-1-yl)-N,N′-bis(phenyl)-9,9-diphenylfluorene); spiro-TAD (2,2′,7,7′-tetrakis(n,n-diphenylamino)-9,9′-spirobifluorene); 9,9-bis[4-(N,N-bisbiphenyl-4-ylamino)phenyl]-9H-fluorene; 9, 9-bis[4-(N,N′-bisnaphthalen-2-ylamino)phenyl]-9H-fluorene; 9, 9-bis[4-(N,N′-bisnaphthalen-2-yl-N,N′-bisphenylamino)phenyl]-9H-fluorene; N,N′-bis(phen-anthren-9-yl)-N,N′-bis(phenyl)benzidine; 2,7-bis[N,N-bis(9,9-spirobifluoren-2-yl)amino]-9,9-spirobifluorene; 2,2′-bis[N,N-bis(biphenyl-4-yl)amino]9,9-spirobifluorene; 2,2′-bis(N,N-diphenylamino)9,9-spirobifluorene; di-[4-(N,N-ditolylamino)phenyl]cyclohexane; 2,2′,7,7′-tetra(N,N-ditolyl)aminospirobifluorene; and N,N,N′,N′-tetranaphthalen-2-ylbenzidine, a tertiary amine, a carbazole derivative, a conductive polyaniline and/or polyethylene dioxythiophene.

The hole transport layer can have a layer thickness in a range of approximately 5 nm to approximately 50 nm, for example in a range of approximately 10 nm to approximately 30 nm, for example approximately 20 nm.

An emitter layer can be formed on or above the hole transport layer. Each of the organic functional layer structure units 316, 320 may include in each case one or a plurality of emitter layers, for example including fluorescent and/or phosphorescent emitters.

An emitter layer may include or be formed from organic polymers, organic oligomers, organic monomers, organic small, non-polymer molecules (“small molecules”) or a combination of these materials.

The optoelectronic component 100 may include or be formed from one or a plurality of the following materials in an emitter layer: organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl(2-carboxypyridyl)iridium III), green phosphorescent Ir(ppy)₃ (tris(2-phenylpyridine)iridium III), red phosphorescent Ru (dtb-bpy)₃*2(PF₆) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di(p-tolyl)amino]anthracene) and red fluorescent DCM2(4-dicyanomethylene)-2-methyl-6-julolidyl-9-enyl-4H-pyran) as non-polymeric emitters.

Such non-polymeric emitters can be deposited for example by thermal evaporation. Furthermore, polymer emitters can be used which can be deposited for example by a wet-chemical method, such as, for example, a spin coating method.

The emitter materials can be embedded in a suitable manner in a matrix material, for example a technical ceramic or a polymer, for example an epoxy; or a silicone.

In various embodiments, the emitter layer can have a layer thickness in a range of approximately 5 nm to approximately 50 nm, for example in a range of approximately 10 nm to approximately 30 nm, for example approximately 20 nm.

The emitter layer may include emitter materials that emit in one color or in different colors (for example blue and yellow or blue, green and red). Alternatively, the emitter layer may include a plurality of partial layers which emit light of different colors. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary radiation and secondary radiation.

The organic functional layer structure unit 316 may include one or a plurality of emitter layers embodied as hole transport layer.

Furthermore, the organic functional layer structure unit 316 may include one or a plurality of emitter layers embodied as electron transport layer.

An electron transport layer can be formed, for example deposited, on or above the emitter layer.

The electron transport layer may include or be formed from one or a plurality of the following materials: NET-18; 2,2′,2″-(1,3,5-benzinetriyl)tris(1-phenyl-1-H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolatolithium, 4-(naphthalen-1-yl)-3,5-diphenyl-4H-1,2,4-triazole; 1,3-bis[2-(2,2′-bipyridin-6-yl)-1,3,4-oxadiazo-5-yl]benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-naphthalen-2-yl)phenyl)-1H-imidazo[4,5-f][1,10]phenanthroline; phenyldipyrenylphosphine oxide; naphthalenetetracarboxylic dianhydride or the imides thereof; perylenetetracarboxylic dianhydride or the imides thereof; and substances based on silols including a silacyclopentadiene unit.

The electron transport layer can have a layer thickness in a range of approximately 5 nm to approximately 50 nm, for example in a range of approximately 10 nm to approximately 30 nm, for example approximately 20 nm.

An electron injection layer can be formed on or above the electron transport layer. The electron injection layer may include or be formed from one or a plurality of the following materials: NDN-26, MgAg, Cs₂CO₃, Cs₃PO₄, Na, Ca, K, Mg, Cs, Li, LiF; 2,2′,2″-(1,3,5-benzinetriyl)tris(1-phenyl-1-H-benzimidazole); 2-(4-biphenylyl)-5-(4-tert-butylphenyl)-1,3,4-oxadiazole, 2,9-dimethyl-4,7-diphenyl-1,10-phenanthroline (BCP); 8-hydroxyquinolinolatolithium, 4-(naphthalen-1-yl)-3,5-diphenyl-4H-1,2,4-triazole; 1,3-bis[2-(2,2′-bipyridin-6-yl)-1,3,4-oxadiazo-5-yl)benzene; 4,7-diphenyl-1,10-phenanthroline (BPhen); 3-(4-biphenylyl)-4-phenyl-5-tert-butylphenyl-1,2,4-triazole; bis(2-methyl-8-quinolinolate)-4-(phenylphenolato)aluminum; 6,6′-bis[5-(biphenyl-4-yl)-1,3,4-oxadiazo-2-yl]-2,2′-bipyridyl; 2-phenyl-9,10-di(naphthalen-2-yl)anthracene; 2,7-bis[2-(2,2′-bipyridin-6-yl)-1,3,4-oxadiazo-5-yl]-9,9-dimethylfluorene; 1,3-bis[2-(4-tert-butylphenyl)-1,3,4-oxadiazo-5-yl]benzene; 2-(naphthalen-2-yl)-4,7-diphenyl-1,10-phenanthroline; 2,9-bis(naphthalen-2-yl)-4,7-diphenyl-1,10-phenanthroline; tris(2,4,6-trimethyl-3-(pyridin-3-yl)phenyl)borane; 1-methyl-2-(4-(naphthalen-2-yl)phenyl)-1H-imidazo[4,5-f][1,10]phenanthroline; phenyldipyrenylphosphine oxide; naphthalenetetracarboxylic dianhydride or the imides thereof; perylenetetracarboxylic dianhydride or the imides thereof;

and substances based on silols including a silacyclopentadiene unit.

The electron injection layer can have a layer thickness in a range of approximately 5 nm to approximately 200 nm, for example in a range of approximately 20 nm to approximately 50 nm, for example approximately 30 nm.

In the case of an organic functional layer structure 312 including two or more organic functional layer structure units 316, 320, the second organic functional layer structure unit 320 can be formed above or alongside the first functional layer structure units 316. An intermediate layer structure 318 can be formed electrically between the organic functional layer structure units 316, 320.

In various embodiments, the intermediate layer structure 318 can be formed as an intermediate electrode 318 for example in accordance with one of the configurations of the first electrode 310. An intermediate electrode 318 can be electrically connected to an external voltage source. The external voltage source can provide a third electrical potential, for example, at the intermediate electrode 318.

However, the intermediate electrode 318 can also have no external electrical connection, for example by the intermediate electrode having a floating electrical potential.

In various embodiments, the intermediate layer structure 318 can be formed as a charge generating layer structure 318 (charge generation layer CGL). A charge generating layer structure 318 may include one or a plurality of electron-conducting charge generating layer(s) and one or a plurality of hole-conducting charge generating layer(s). The electron-conducting charge generating layer(s) and the hole-conducting charge generating layer(s) can be formed in each case from an intrinsically conductive substance or a dopant in a matrix. The charge generating layer structure 318 should be formed, with respect to the energy levels of the electron-conducting charge generating layer(s) and the hole-conducting charge generating layer(s), in such a way that electron and hole can be separated at the interface between an electron-conducting charge generating layer and a hole-conducting charge generating layer. The charge generating layer structure 318 can furthermore have a diffusion barrier between adjacent layers.

Each organic functional layer structure unit 316, 320 can have for example a layer thickness of a maximum of approximately 3 μm, for example a layer thickness of a maximum of approximately 1 μm, for example a layer thickness of a maximum of approximately 300 nm.

The optoelectronic component 100 can optionally include further organic functional layers, for example arranged on or above the one or the plurality of emitter layers or on or above the electron transport layer(s). The further organic functional layers can be for example internal or external coupling-in/coupling-out structures that further improve the functionality and thus the efficiency of the optoelectronic component 100.

The second electrode 314 can be formed on or above the organic functional layer structure 312 or, if appropriate, on or above the one or the plurality of further organic functional layer structures and/or organic functional layers.

The second electrode 314 can be formed in accordance with one of the configurations of the first electrode 310, wherein the first electrode 310 and the second electrode 314 can be formed identically or differently. The second electrode 314 can be formed as an anode, that is to say as a hole-injecting electrode, or as a cathode, that is to say as an electron-injecting electrode.

In various embodiments, the first electrically conductively formed layer 106 can be formed as first electrode 310 and/or a second electrode 314 and/or can be electrically connected thereto. In one embodiment, the first electrode and/or the second electrode can be the second electrically conductively formed layer.

The second electrode 314 can have a second electrical terminal, to which a second electrical potential can be applied. The second electrical potential can be provided by the same energy source as, or a different energy source than, the first electrical potential and/or the optional third electrical potential. The second electrical potential can be different than the first electrical potential and/or the optionally third electrical potential. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 3 V to approximately 12 V.

The second barrier layer 308 can be formed on the second electrode 314.

The second barrier layer 308 can be formed in accordance with one of the configurations of the first barrier layer 304. The electrically conductively formed thin film encapsulation 106 can be formed in various embodiments in accordance with one of the configurations of the first barrier layer 304 and/or the second barrier layer 308, for example as first barrier layer 304 and/or second barrier layer 308.

Furthermore, it should be pointed out that, in various embodiments, a second barrier layer 308 can also be entirely dispensed with. In such a configuration, the optoelectronic component 100 may include for example a further encapsulation structure, as a result of which a second barrier layer 308 can become optional, for example a cover 324, for example a cavity glass encapsulation or metallic encapsulation.

Furthermore, in various embodiments, in addition, one or a plurality of coupling-in/-out layers can also be formed in the optoelectronic component 100, for example an external coupling-out film on or above the carrier 102 (not illustrated) or an internal coupling-out layer (not illustrated) in the layer cross section of the optoelectronic component 100. The coupling-in/-out layer may include a matrix and scattering centers distributed therein, wherein the average refractive index of the coupling-in/-out layer is greater than the average refractive index of the layer from which the electromagnetic radiation is provided. Furthermore, in various embodiments, in addition, one or a plurality of antireflection layers (for example combined with the second barrier layer 308) can be provided in the optoelectronic component 100.

In various embodiments, a close connection layer 322, for example composed of an adhesive or a lacquer, can be provided on or above the second barrier layer 308. By the close connection layer 322, a cover 324 can be closely connected, for example adhesively bonded, on the second barrier layer 308.

A close connection layer 322 composed of a transparent material may include for example particles which scatter electromagnetic radiation, for example light-scattering particles. As a result, the close connection layer 322 can act as a scattering layer and lead to an improvement in the color angle distortion and the coupling-out efficiency.

The light-scattering particles provided can be dielectric scattering particles, for example composed of a metal oxide, for example silicon oxide (SiO₂), zinc oxide (ZnO), zirconium oxide (ZrO₂), indium tin oxide (ITO) or indium zinc oxide (IZO), gallium oxide (Ga₂Oₓ), aluminum oxide, or titanium oxide. Other particles may also be suitable provided that they have a refractive index that is different than the effective refractive index of the matrix of the close connection layer 322, for example air bubbles, acrylate, or hollow glass beads. Furthermore, by way of example, metallic nanoparticles, metals such as gold, silver, iron nanoparticles, or the like can be provided as light-scattering particles.

The close connection layer 322 can have a layer thickness of greater than 1 μm, for example a layer thickness of a plurality of μm. In various embodiments, the close connection layer 322 may include or be a lamination adhesive.

The close connection layer 322 can be designed in such a way that it includes an adhesive having a refractive index that is less than the refractive index of the cover 324. Such an adhesive can be for example a low refractive index adhesive such as, for example, an acrylate having a refractive index of approximately 1.3. However, the adhesive can also be a high refractive index adhesive which for example includes high refractive index, non-scattering particles and has a layer-thickness-averaged refractive index that approximately corresponds to the average refractive index of the organic functional layer structure 312, for example in a range of approximately 1.7 to approximately 2.0. Furthermore, a plurality of different adhesives can be provided which form an adhesive layer sequence.

In various embodiments, between the second electrode 314 and the close connection layer 322, an electrically insulating layer (not shown) can also be applied, for example SiN, for example having a layer thickness in a range of approximately 300 nm to approximately 1.5 μm, for example having a layer thickness in a range of approximately 500 nm to approximately 1 μm, in order to protect electrically unstable materials, during a wet-chemical process for example.

In various embodiments, a close connection layer 322 can be optional, for example if the cover 324 is formed directly on the second barrier layer 308, for example a cover 324 composed of glass that is formed by plasma spraying.

Furthermore, a so-called getter layer or getter structure, for example a laterally structured getter layer, can be arranged (not illustrated) on or above the electrically active region 306.

The getter layer can have a layer thickness of greater than approximately 1 μm, for example a layer thickness of a plurality of μm.

In various embodiments, the getter layer may include a lamination adhesive or be embedded in the close connection layer 322.

A cover 324 can be formed on or above the close connection layer 322. The cover 324 can be closely connected to the electrically active region 306 by the close connection layer 322 and can protect said region from harmful substances. The cover 324 can be for example a glass cover 324, a metal film cover 324 or a sealed plastics film cover 324. The glass cover 324 can be closely connected to the second barrier layer 308 or the electrically active region 306 for example by frit bonding (glass soldering/seal glass bonding) by a conventional glass solder in the geometric edge regions of the organic optoelectronic component 100.

The cover 324 and/or the close connection layer 322 can have a refractive index (for example at a wavelength of 633 nm) of 1.55.

In various embodiments, further layers can be arranged between a hermetically impermeable substrate 128, an encapsulation structure 126 and/or a carrier 302; and the first electrically conductively formed layer 102. The further layers can have for example an optical, electrical and/or encapsulating functionality.

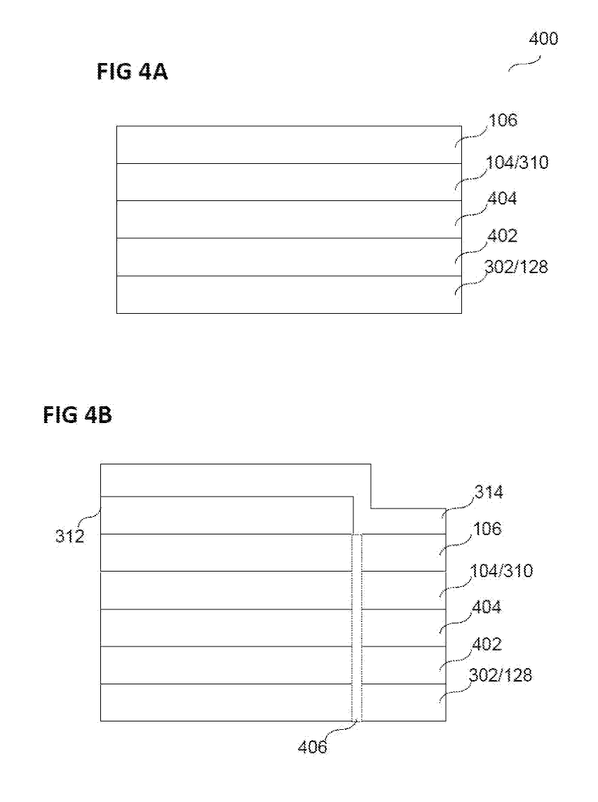

In one embodiment (illustrated in FIG. 4A), a layer stack including a scattering film 402, a planarization layer 404 and a binder-containing anode 310/104 is formed, for example deposited, for example over the whole area, on or above a carrier 302 or hermetically impermeable substrate 128 (see description above).

The scattering film 402 can be for example a polymeric scattering film, for example in accordance with one of the configurations of the coupling-out layer—see description above.

The planarization layer 404 can be formed for smoothing the surface, for example for reducing the surface roughness of the scattering film 402, for example in accordance with one of the configurations of a barrier layer—see description above.

The binder-containing anode 310/104 can be formed as first electrode 310 and first electrically conductively formed layer 104—see description above.

On the electrically conductively formed thin film encapsulation 106, the further layers of the optoelectronic component 100 can be formed, for example the organic functional layer structure 312 and the second electrode 314—illustrated in FIG. 4B—also see description above.

Illustratively, in various embodiments, an electrically conductive, for example electrically conductively formed thin film encapsulation 106 (conductive/conducting thin film encapsulation—CTFE) is formed between at least one of the electrodes 310, 314 and the organic functional layer structure 312, wherein the electrically conductively formed thin film encapsulation 106 is hermetically impermeable with respect to a diffusion of water and/or oxygen through the CTFE; and an electric current, for example the electric operating current of the optoelectronic component 100, is conducted through the electrically conductively formed thin film encapsulation 106 during the operation of the optoelectronic component 100. In one embodiment, the electrically conductively formed thin film encapsulation 106 can be formed as at least translucent. In other words: the electrically conductively formed thin film encapsulation 106 can be water-impermeable, transparent and conductive. In one embodiment, the electrically conductively formed thin film encapsulation 106 includes for example zinc oxide and aluminum, for example a mixture of zinc oxide and aluminum (ZnO:Al). The electrically conductively formed thin film encapsulation 106 can have a relatively low conductivity along the areal dimensioning, for example a relatively low transverse conductivity, since the current is distributed along the areal dimensioning in the electrode 310, 314 with the nanowires or nanotubes. The electrically conductively formed thin film encapsulation 104 should therefore have a sufficiently high electrical conductivity perpendicular to the areal extent of the thin film encapsulation 106—parallel to the surface normal of the thin film encapsulation 106.

The electrode 110, 114, adjoining the electrically conductively formed thin film encapsulation 104 may include a binder, for example. By way of example, silver nanowires and/or carbon nanotubes can be distributed in the binder.

After the layer stack including layers in which water and/or oxygen can diffuse and which is electrically conductive at least at the surface has been formed, an electrically conductive but water-tight and transparent thin film encapsulation 106 can be formed. The layers of the layer stack can be structured arbitrarily by a laser process. Water penetrating into the water-conducting layers can diffuse horizontally, but cannot leave the layer stack vertically. Thus, in the further course of the method, for example, an OLED can be produced according to conventional methods.

After forming the electrically conductively formed thin film encapsulation 106 on the binder-containing anode 310/104, that is to say after the binder-containing anode 310/104 has been electrically conductively encapsulated by the electrically conductively formed thin film encapsulation 106, the layer stack can be structured, for example structured by a laser process.

The water-conducting layers, for example the binder-containing anode 310/104, are separated from the organic functional layer structure 312 by the electrically conductively formed thin film encapsulation 106. As a result, the organic functional layer structure 312 can no longer be damaged by water and/or oxygen. A structured deposition of the first electrically conductively formed layer 104, for example of the silver nanowires or carbon nanotubes, or of similar structures embedded in a binder with high electrical conductivity, can be formed optionally in a structured fashion. Furthermore, existing processes and layouts can be used for forming the optoelectronic component.

In one configuration, the electrically conductively formed thin film encapsulation 106 can be electrically conductively connected to the first electrode 312 and the second electrode 314 and be structured in such a way that that region of the electrically conductively formed thin film encapsulation 106 which is electrically conductively connected to the first electrode 312 is electrically insulated from that region of the electrically conductively formed thin film encapsulation 106 which is electrically conductively connected to the second electrode 314. The structuring can be formed for example as laser ablation or laser fusion—illustrated in FIG. 4B by the region 406.

In various embodiments, an optoelectronic component and a method for producing an optoelectronic component are provided which make it possible to form stabler optoelectronic components including a binder-containing electrode. Furthermore, existing processes for producing the optoelectronic component and layouts of the optoelectronic component can be used.

1. An optoelectronic component comprising:
a first electrically conductively formed layer, comprising an electrically conductive substance in a matrix;
a second electrically conductively formed layer; and
an electrically conductively formed thin film encapsulation between the first electrically conductively formed layer and the second electrically conductively formed layer;
wherein the electrically conductively formed thin film encapsulation is formed in such a way that the second electrically conductively formed layer is electrically conductively connected to the first electrically conductively formed layer by the electrically conductively formed thin film encapsulation, and
wherein the electrically conductively formed thin film encapsulation is formed in a hermetically impermeable fashion with respect to a diffusion of water and/or oxygen from the first electrically conductively formed layer through the electrically conductively formed thin film encapsulation into the second electrically conductively formed layer.

2. The optoelectronic component as claimed in claim 1,
wherein the optoelectronic component is formed as an organic optoelectronic component.

3. The optoelectronic component as claimed in claim 1,
wherein the first electrically conductively formed layer, the electrically conductively formed thin film encapsulation and the second electrically conductively formed layer are formed as a layer stack.

4. The optoelectronic component as claimed in claim 1,
wherein the matrix comprises or is formed from a binder with respect to the electrically conductive substance.

5. The optoelectronic component as claimed in claim 1,
wherein the matrix is formed in a cohesion-reinforcing fashion with regard to the cohesion of the electrically conductive substance.

6. The optoelectronic component as claimed in claim 1,
wherein the matrix of the first electrically conductively formed layer is hygroscopic.

7. The optoelectronic component as claimed in claim 1,
wherein the electrically conductive substance is formed as particles in a form from one of the forms from the group of forms: nanowires, nanotubes, flakes or laminae.

8. The optoelectronic component as claimed in claim 1,
wherein the electrically conductively formed thin film encapsulation comprises or is formed from a dopant in a matrix.

9. The optoelectronic component as claimed in claim 1,
wherein the electrically conductively formed thin film encapsulation comprises or is formed from an alloy.

10. The optoelectronic component as claimed in claim 1,
wherein the diffusion rate with respect to water and/or oxygen through the electrically conductively formed thin film encapsulation is less than approximately 10⁻⁴ g/(m²d).

11. The optoelectronic component as claimed in claim 1,
wherein the optoelectronic component comprises a first electrode, a second electrode and an organic functional layer structure between the first electrode and the second electrode, wherein the organic functional layer structure is formed for converting an electric current into an electromagnetic radiation and/or for converting an electromagnetic radiation into an electric current; wherein the first electrically conductively formed layer is formed as first electrode and/or second electrode; and wherein the second electrically conductively formed layer is formed as the organic functional layer structure, or a layer or structure in the organic functional layer structure.

12. The optoelectronic component as claimed in claim 1,
further comprising an encapsulation structure, wherein the encapsulation structure comprises the electrically conductively formed thin film encapsulation, and wherein the encapsulation structure is formed in such a way that the second electrically conductively formed layer is hermetically sealed with respect to a diffusion of water through the encapsulation structure into the second electrically conductively formed layer.

13. The optoelectronic component as claimed in claim 1,
further comprising at least one charge carrier injection layer between the electrically conductively formed thin film encapsulation and the first electrically conductively formed layer and/or between the electrically conductively formed thin film encapsulation and the second electrically conductively formed layer.

14. A method for producing an optoelectronic component, the method comprising:
forming a first electrically conductive layer comprising an electrically conductive substance in a matrix in such a way that the first electrically conductive layer conducts at least part of the electric operating current during the operation of the optoelectronic component;
forming a second electrically conductive layer in such a way that the second electrically conductive layer conducts at least part of the electric operating current during the operation of the optoelectronic component; and
forming an electrically conductive thin film encapsulation (106) between the first electrically conductively formed layer and the second electrically conductively formed layer,
wherein the electrically conductively formed thin film encapsulation is formed in such a way that the second electrically conductively formed layer is electrically conductively connected to the first electrically conductively formed layer by the electrically conductively formed thin film encapsulation at least during the operation of the optoelectronic component, and
wherein the electrically conductive thin film encapsulation is formed in a hermetically impermeable fashion with respect to a diffusion of water and/or oxygen from the first electrically conductively formed layer through the electrically conductively formed thin film encapsulation into the second electrically conductively formed layer.

15. The method as claimed in claim 14, further comprising:
forming a first electrode and forming a second electrode, wherein the first electrode and the second electrode are formed in a manner electrically conductively connected to the electrically conductive thin film encapsulation; and
wherein the electrically conductive thin film encapsulation is structured in such a way that that region of the electrically conductive thin film encapsulation which is electrically conductively connected to the first electrode is electrically insulated from that region of the electrically conductively formed thin film encapsulation which is electrically conductively connected to the second electrode.
